(19) United States
(12) Patent Application Publication
(10) Pub. No.: US 2022/0352335 A1
(43) Pub. Date: Nov. 3, 2022

(54) NANOWIRE/NANOSHEET DEVICE WITH SUPPORT PORTION, METHOD OF MANUFACTURING THE SAME AND ELECTRONIC APPARATUS

(71) Applicant: INSTITUTE OF MICROELECTRONICS, CHINESE ACADEMY OF SCIENCES, Beijing (CN)

(72) Inventor: Huilong ZHU, Poughkeepsie, NJ (US)

(21) Appl. No.: 17/731,853

(22) Filed: Apr. 28, 2022

(30) Foreign Application Priority Data
Apr. 29, 2021 (CN) 202110477577.1

(51) Int. Cl. H01L 29/423; H01L 29/06; H01L 29/786; H01L 27/088; H01L 29/66

(52) U.S. Cl. CPC H01L 29/42392; H01L 29/0673; H01L 29/78696; H01L 27/088; H01L 29/66545

(57) ABSTRACT

Provided are a nanowire/nanosheet device with a support portion, a method of manufacturing the nanowire/nanosheet device, and an electronic apparatus including the nanowire/nanosheet device. According to the embodiments, the nanowire/nanosheet device may include: a substrate; a first source/drain layer and a second source/drain layer opposite to each other in a first direction on the substrate; a first nanowire/nanosheet spaced apart from a surface of the substrate and extending from the first source/drain layer to the second source/drain layer; one or more support portions penetrating the first nanowire/nanosheet in a direction perpendicular to the surface of the substrate; and a gate stack extending in a second direction to surround the first nanowire/nanosheet, wherein the second direction intersects the first direction.

### CROSS REFERENCE

This application claims the benefit of Chinese Patent Application No. 202110477577.1, filed on Apr. 29, 2021 in the China National Intellectual Property Administration, the whole disclosure of which is incorporated herein by reference in its entirety.

### TECHNICAL FIELD

The present disclosure relates to a field of semiconductor, and in particular to a nanowire/nanosheet device with a support portion, a method of manufacturing the nanowire/nanosheet device, and an electronic apparatus including the nanowire/nanosheet device.

### BACKGROUND

A nanowire or nanosheet (hereinafter referred to as “nanowire/nanosheet”) device, especially a nanowire/nanosheet-based Gate-All-Around (GAA) Metal Oxide Semiconductor Field Effect Transistor (MOSFET), may control a short channel effect well and achieve a further miniaturization of the device. However, with an increasing miniaturization, it is difficult to avoid an adhesion of nanowires/nanosheets during a manufacturing process.

### SUMMARY

In view of this, the purpose of the present disclosure is at least partly to provide a nanowire/nanosheet device with a support portion, a method of manufacturing the same and an electronic apparatus including the nanowire/nanosheet device

According to one aspect of the present disclosure, a nanowire/nanosheet device is provided, including: a substrate; a first source/drain layer and a second source/drain layer opposite to each other in a first direction on the substrate; a first nanowire/nanosheet spaced apart from a surface of the substrate and extending from the first source/drain layer to the second source/drain layer; one or more support portions penetrating the first nanowire/nanosheet in a direction perpendicular to the surface of the substrate; and a gate stack extending in a second direction to surround the first nanowire/nanosheet, wherein the second direction intersects the first direction.

According to another aspect of the present disclosure, a method of manufacturing a nanowire/nanosheet device is provided, including: forming a stack of one or more gate defining layers and one or more nanowire/nanosheet defining layers alternately arranged on a substrate; patterning the stack into a linear shape or a sheet shape extending in a first direction, with one or more openings penetrating the stack in a direction perpendicular to a surface of the substrate; forming a support portion in the one or more openings; forming another gate defining layer on the substrate to cover the stack; patterning the another gate defining layer into a strip shape extending in a second direction intersecting the first direction; patterning the stack by using the strip-shaped another gate defining layer as a mask, wherein the patterned nanowire/nanosheet defining layer forms a nanowire/nanosheet, and the patterned gate defining layer and the another gate defining layer form a dummy gate; and replacing the dummy gate with a gate stack.

According to another aspect of the present disclosure, an electronic apparatus is provided, including the nanowire/nanosheet device described above.

According to the embodiments of the present disclosure, the support portion may be provided to support the nanowire/nanosheet to prevent the nanowire/sheet from collapsing or adhering to each other during the manufacturing process, especially when the gate length is greater than 100 nm.

### BRIEF DESCRIPTION OF THE DRAWINGS

Through the following descriptions of embodiments of the present disclosure with reference to the drawings, the above and other objectives, features and advantages of the present disclosure will be more apparent. In the drawings:

FIG. 1 to FIG. 17(b) illustrate schematic diagrams of some stages in a process of manufacturing a nanowire/nanosheet device according to an embodiment of the present disclosure;

FIG. 18(a) to FIG. 22 illustrate schematic diagrams of some stages in a process of manufacturing a nanowire/nanosheet device according to another embodiment of the present disclosure, in which

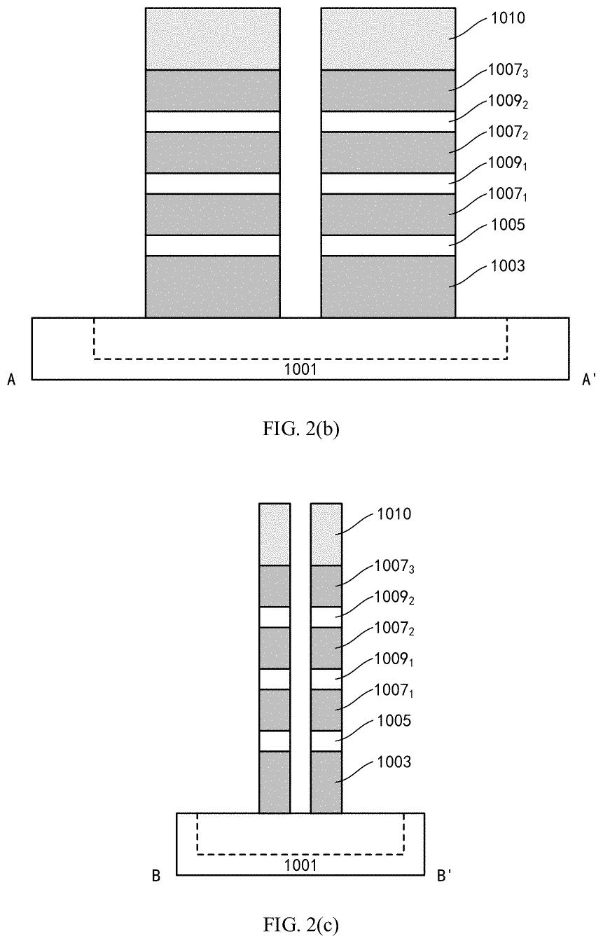

FIGS. 2(a), 3, and 7(a) are top views, and FIG. 2(a) shows positions of line AA′ and line BB′,

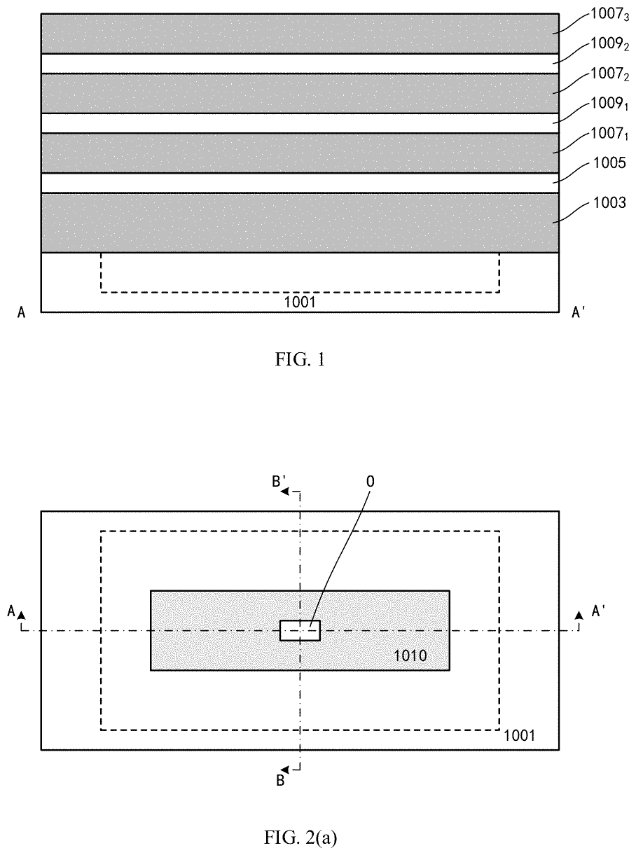

FIGS. 1, 2(b), 4(a), 5(a), 6(a), 7(b), 8, 9, 10(a), 11, 12(a), 13(a), 14 (a), 15(a), 16(a), 17(a), 18(a), 19(a), 20(a), 21, 22 are cross-sectional views taken along the line AA′,

FIGS. 2(c), 4(b), 5(b), 6(b), 10(b), 12(b), 13(b), 14(b), 15(b), 16(b), 17(b), 18(b), 19(b), 20(b) are cross-sectional views taken along the line BB′.

Throughout the drawings, the same or similar reference numerals indicate the same or similar components.

### DETAILED DESCRIPTION OF EMBODIMENTS

Hereinafter, the embodiments of the present disclosure will be described with reference to the drawings. However, it should be understood that these descriptions are only exemplary, and are not intended to limit the scope of the present disclosure. Moreover, in the following descriptions, descriptions of well-known structures and technologies are omitted to avoid unnecessarily obscuring the concept of the present disclosure.

Various schematic structural diagrams according to the embodiments of the present disclosure are shown in the drawings. The drawings are not drawn to scale. Some details are enlarged and some details may be omitted for clarity of presentation. Shapes of the various regions, layers and a relative size and a positional relationship thereof shown in the drawings are only exemplary. In practice, there may be deviations due to manufacturing tolerances or technical limitations, and those skilled in the art may additionally design regions/layers with different shapes, sizes, and relative positions according to actual needs.

In the context of the present disclosure, when a layer/element is referred to as being located “on” another layer/element, the layer/element may be directly on the another layer/element, or there may be an intermediate layer/element therebetween. In addition, if a layer/element is located “on” another layer/element in one orientation, the layer/element may be located “under” the another layer/element when the orientation is reversed.

According to the embodiments of the present disclosure, there is provided a nanowire/nanosheet device. In particular, the device may include one or more nanowires or nanosheets used as a channel. The nanowire/nanosheet may be suspended with respect to a substrate and may extend substantially parallel to a surface of the substrate. The nanowire/nanosheet may extend in a first direction between source/drain layers opposite to each other. The source/drain layer may contain a semiconductor material different from that of the nanowire/nanosheet in order to realize stress engineering. In addition, a gate stack may extend in a second direction intersecting (e.g., perpendicular to) the first direction so as to intersect each nanowire/nanosheet, and thus may surround a periphery of each nanowire/nanosheet, so that a Gate-All-Around (GAA) structure may be formed.

According to the embodiments of the present disclosure, a support portion penetrating the nanowire/nanosheets in a vertical direction (for example, a direction substantially perpendicular to the surface of the substrate) may be provided to inhibit a collapse or an adhesion of the nanowire/nanosheets in a manufacturing process. In addition, the nanowires/nanosheets at different heights may be substantially aligned in the vertical direction.

The support portion may be formed of a dielectric material in order to physically support the nanowire/nanosheets. Alternatively, the support portion may include a laminate of a dielectric material and a conductive material. The laminate is similar to the gate stack and may thus be used as an inner gate of the device. By applying a bias to the inner gate, a current between the source/drain layer may be controlled or a threshold voltage of the device may be dynamically adjusted.

Such a semiconductor device may be manufactured, for example, as follows. One or more nanowire/nanosheet defining layers (spaced apart from each other in a case of a plurality of nanowire/nanosheet defining layers) spaced apart from the substrate may be provided on the substrate. Device manufacturing may be performed based on the nanowire/nanosheet defining layer. For example, a dummy gate may be formed, and a spacer may be formed on a sidewall of the dummy gate. An end of the nanowire/nanosheet defining layer may be exposed through the spacer. A source/drain layer connected to the nanowire/nanosheet defining layer may be formed at the end of the nanowire/nanosheet defining layer. The dummy gate may be replaced with a gate stack by a replacement gate process.

In order to provide the nanowire/nanosheet defining layer spaced apart from the substrate, a stack of one or more gate defining layers and one or more nanowire/nanosheet defining layers alternately arranged may be formed on the substrate. In addition, in consideration of electrical isolation, an isolation portion defining layer may be provided under the stack. The gate defining layer, the nanowire/nanosheet defining layer and the isolation portion defining layer may be formed on the substrate by epitaxial growth. The stack may be patterned into a preliminary nanowire/nanosheet extending in the first direction. A length of the preliminary nanowire/nanosheet in the first direction may be greater than a length of a nanowire/nanosheet to be finally formed in the first direction, so as to subsequently form a nanowire/nanosheet self-aligned with the dummy gate. In the patterning step, the isolation portion defining layer may also be patterned. Thus, the isolation portion defining layer may be self-aligned to the preliminary nanowire/nanosheet.

In addition, at the same time or in addition to patterning the preliminary nanowire/nanosheet, an opening penetrating the stack in the vertical direction may be formed. In the opening, the support portion may be formed to support the preliminary nanowire/nanosheet to inhibit a collapse or an adhesion of the preliminary nanowire/nanosheet in the subsequent process.

So far, the gate defining layer also has a shape extending in the first direction. In order to form an all-around gate, another gate defining layer may be further formed and patterned into a strip shape extending in the second direction. The strip-shaped another gate defining layer may be used as a mask to pattern preliminary nanowire/nanosheet under the another gate defining layer. The strip-shaped another gate defining layer together with other gate defining layers may constitute a dummy gate extending in the second direction, and the nanowire/nanosheet defining layer may be patterned into a nanowire/nanosheet self-aligned with and surrounded by the dummy gate. The isolation portion defining layer may also be patterned in the patterning step, and the isolation portion defining layer may be self-aligned with the nanowire/nanosheet.

In order to form a self-aligned spacer, the dummy gate may be selectively etched so that a sidewall of the dummy gate is recessed inwardly with respect to a sidewall of the nanowire/nanosheet, and the spacer may be formed in a recess thus formed.

The present disclosure may be presented in various forms, some examples of which will be described below. In the following descriptions, a selection of various materials is involved. In the selection of the material, in addition to a function of the material (for example, a semiconductor material may be used for forming an active region, a dielectric material may be used for forming an electrical isolation, and a conductive material may be used for forming an electrode, an interconnect structure, etc.), an etching selectivity is also considered. In the following descriptions, a required etching selectivity may or may not be indicated. It should be clear to those skilled in the art that when etching a material layer is mentioned below, if it is not mentioned or shown that other layers are also etched, then the etching may be selective, and the material layer may have etching selectivity relative to other layers exposed to the same etching recipe.

FIG. 1 to FIG. 17(b) show schematic diagrams of some stages in a process of manufacturing a nanowire/nanosheet device according to the embodiments of the present disclosure.

As shown in FIG. 1, a substrate 1001 is provided. The substrate 1001 may be in various forms, including but not limited to a bulk semiconductor material substrate such as a bulk Si substrate, a semiconductor-on-insulator (SOI) substrate, a compound semiconductor substrate such as a SiGe substrate, and the like. In the following descriptions, for ease of explanation, a bulk Si substrate such as a Si wafer is taken as an example for description.

A well region as indicated by a dotted line in FIG. 1 may be formed in the substrate 1001. For example, if an n-type device is to be formed on the substrate 1001, a p-type doped well region may be formed; and if a p-type device is to be formed on the substrate 1001, an n-type doped well region may be formed. A doping concentration of the well region may be about 1E17-1E 19 cm⁻³.

An isolation portion defining layer 1003 may be formed on the substrate 1001 to define a position of an isolation portion to be subsequently formed. An etch stop layer 1005 may be formed on the isolation portion defining layer 1003. The etch stop layer 1005 may set a stop position when the isolation portion defining layer 1003 is subsequently etched, especially in a case that the isolation portion defining layer 1003 having no etching selectivity or low etching selectivity relative to gate defining layers (e.g., 1007₁, 1007₂, 1007₃) subsequently formed. Alternatively, the etch stop layer 1005 may be omitted in a case that the isolation portion defining layer 1003 has etching selectivity relative to the gate defining layers subsequently formed.

A stack of alternately arranged gate defining layers 1007₁, 1007₂, 1007₃ and nanowire/nanosheet defining layers 1009₁, 1009₂ may be formed on the etch stop layer 1005. The gate defining layers 1007₁, 1007₂, 1007₃ may be used to define a position of a gate stack to be subsequently formed, and the nanowire/nanosheet defining layers 1009₁, 1009₂ may be used to define a position of a nanowire/nanosheet to be subsequently formed. An uppermost layer in the stack may be the gate defining layer 1007₃, so that the nanowire/nanosheet defining layers 1009₁, 1009₂ may be covered by the gate defining layers on top and bottom, so that a gate-all-around configuration may be subsequently formed. In this example, two nanowire/nanosheet defining layers 1009₁, 1009₂ may be formed, and thus two layers of nanowires/nanosheets may be formed in a final device. However, the present disclosure is not limited to this. The number of nanowire/nanosheet defining layers to be formed may be determined, and the number of gate defining layers to be formed may be determined correspondingly, based on the number of layers (which may be one or more) of nanowires/nanosheets to be finally formed.

The isolation portion defining layer 1003, the etch stop layer 1005, the gate defining layers 1007₁, 1007₂, 1007₃ and the nanowire/nanosheet defining layers 1009₁, 1009₂ may be semiconductor layers formed on the substrate 1001 by, for example, epitaxial growth. The nanowire/nanosheet defining layers 1009₁, 1009₂ may then have a good crystalline quality and may be of a single crystalline structure, so as to subsequently provide a single crystalline nanowire/nanosheet used as a channel. Adjacent semiconductor layers of the semiconductor layers may have etching selectivity with each other, so as to be subsequently processed differently. For example, the etch stop layer 1005 and the nanowire/nanosheet defining layers 1009₁, 1009₂ may contain Si, and the isolation portion defining layer 1003 and the gate defining layers 1007₁, 1007₂, 1007₃ may contain SiGe (an atomic percentage of Ge is, for example, about 10% to 40%, and may be gradually changed to reduce defects). Each semiconductor layer may have a substantially uniform thickness, so as to extend substantially parallel to a surface of the substrate 1001. For example, a thickness of the isolation portion defining layer 1003 may be about 30 nm to 80 nm, a thickness of the etch stop layer 1005 may be about 3 nm to 15 nm, a thickness of the nanowire/nanosheet defining layers 1009₁, 1009₂ may be about 5 nm to 15 nm, a thickness of the gate defining layer 1007₁ may be about 30 nm to 80 nm, a thickness of the gate defining layer 1007₂ may be about 20 nm to 40 nm, and a thickness of the gate defining layer 1007₃ may be about 30 nm to 50 nm. Here, the gate defining layer 1007₂ between the nanowire/nanosheet defining layers 1009₁ and 1009₂ may be relatively thin, and the gate defining layer 1007₃ on an upper side of the nanowire/nanosheet defining layer 1009₂ and the gate defining layer 1007₁ on a lower side of the nanowire/nanosheet defining layer 1009₁ may be relatively thick.

Next, a nanowire/nanosheet may be patterned. For example, as shown in FIG. 2(a), FIG. 2(b) and FIG. 2(c), a mask such as a photoresist 1010 may be formed on the above-mentioned stack, and the photoresist 1010 may be patterned into a sheet or wire shape by photolithography. A pattern of the photoresist 1010 may be determined according to a shape and a size of a finally desired channel to be formed, which will be apparent according to the following descriptions. In addition, in the pattern of the photoresist 1010, an opening O may be formed, through which a support portion may be subsequently defined. Then, by using the photoresist 1010 as a mask, each layer on the substrate 1001 may be selectively etched sequentially by, for example, Reactive Ion Etching (RIE), and the etching may stop at the substrate 1001. The RIE may be performed in a vertical direction. In this way, each layer on the substrate 1001 may be patterned into a preliminary nanowire or nanosheet corresponding to the photoresist 1010, and as shown in FIG. 2(b) and FIG. 2(c), openings corresponding to the opening O may be formed in the preliminary nanowire or nanosheets. After that, the photoresist 1010 may be removed.

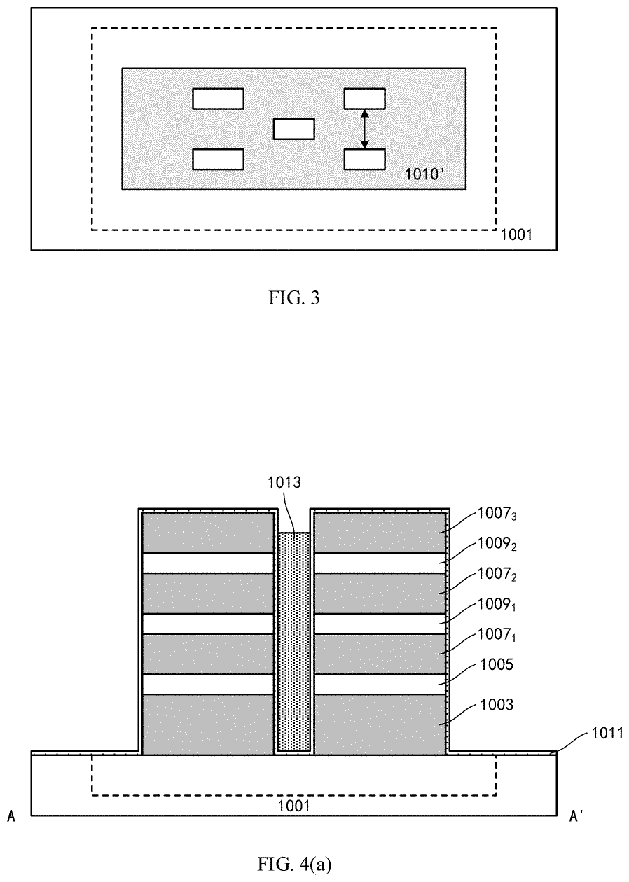

In this example, the opening O is a substantially rectangle formed at a center of the photoresist 1010 whose minimum dimension (a width in the case of the rectangle) may be about 5 nm to 30 nm. However, the present disclosure is not limited to this. For example, the opening O may be formed in other shapes and may be formed in plural. FIG. 3 illustrates a photoresist 1010′ according to another embodiment, in which a plurality of substantially rectangular openings are formed. A device performance, such as conduction current, power consumption, etc., may be optimized by adjusting a size and/or spacing of the openings. For example, as shown by the arrowed line segment in FIG. 3, the spacing between adjacent openings may be about 5 nm to 20 nm.

In addition, the openings defined in the nanowire/nanosheet defining layers 1009₁ and 1009₂ through the openings in the photoresist may provide a selection of additional channel planes and crystal planes to enhance the device performance such as conduction current, etc. In the example of FIGS. 2(a) to 2(c) and FIG. 3, the openings in the photoresist 1010, 1010′ have sides in an extension direction (a vertical direction on the paper surface in FIG. 2(a) and FIG. 3) of a (dummy) gate to be subsequently formed and sides in a direction (a horizontal direction on the paper surface in FIG. 2(a) and FIG. 3) perpendicular to the extension direction of the (dummy) gate. For example, shapes of the openings may be changed, so that at least part of the sides is angled relative to the directions to provide different orientations.

Hereinafter, for convenience, a condition in FIGS. 2(a) to 2(c) is taken as an example for description.

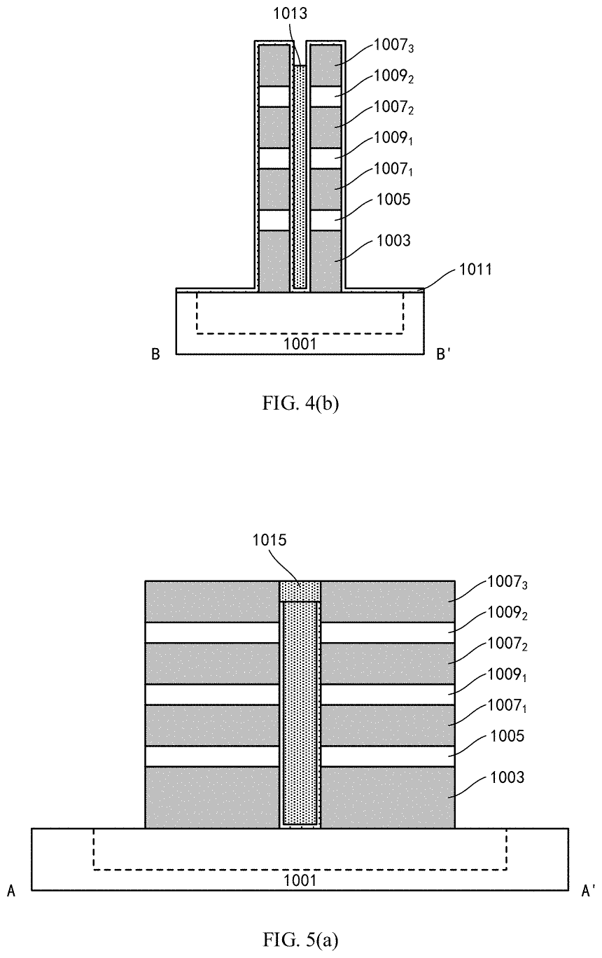

The support portion may be formed in the openings. For example, as shown in FIGS. 4(a) and 4(b), a support body 1013 may be formed in the opening by, for example, deposition and then etch back. In order to protect the stack during the etch back, a thin protective layer 1011 may be formed first. For example, the protective layer 1011 may include an oxide (for example, silicon oxide) formed by thermal oxidation or deposition (for example, atomic layer deposition (ALD) to better control a film thickness), with a thickness of about 0.5 nm to 5 nm. The support body 1013 may include a material having etching selectivity relative to the protective layer 1011, such as a nitride (for example, silicon nitride). The photoresist may be combined to etch back the nitride. For example, the photoresist may be used to shield a region where the opening is located, and the nitride that is not shielded by the photoresist may be removed by the etch back (for example, RIE) (the protective layer 1011 may be used as a stop point of the etch back). Then, the photoresist may be removed, and the nitride exposed due to a removal of the photoresist may be etched back, so that the nitride may be left in the opening, thereby forming the support body 1013.

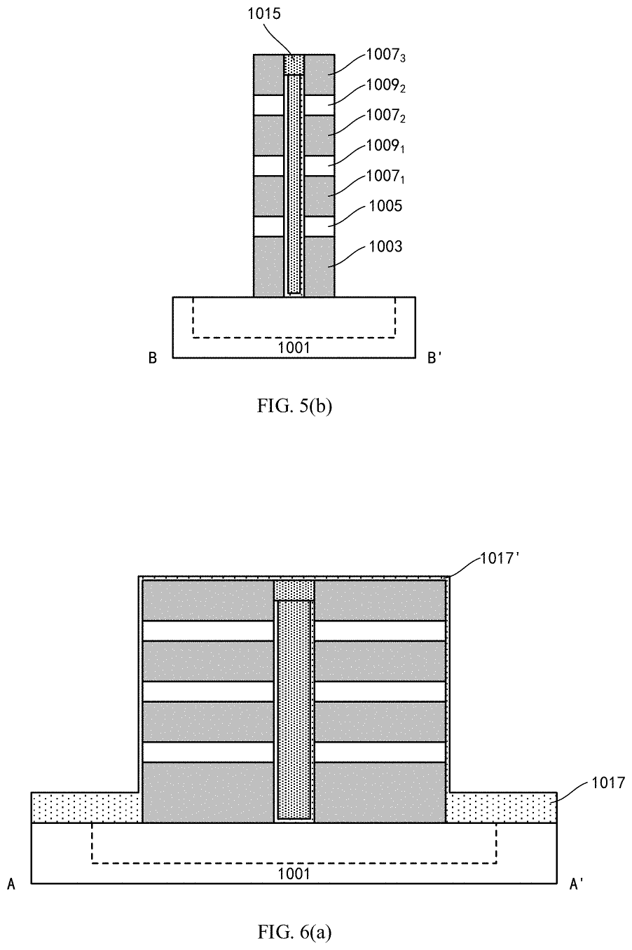

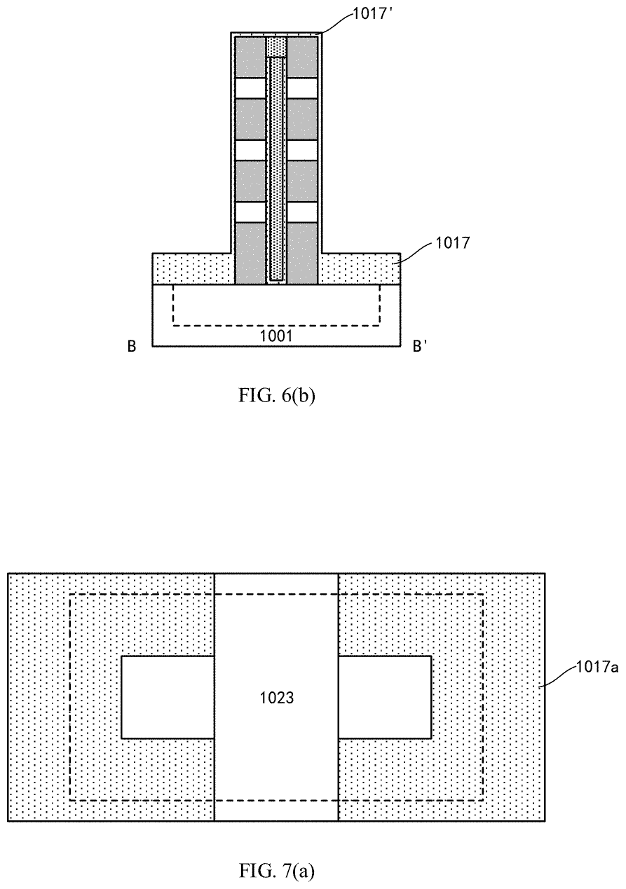

Next, as shown in FIGS. 5(a) and 5(b), the protective layer 1011 may be removed by selective etching to expose the stack. A part of the protective layer 1011 between the stack and the support body 1013 may be remained. In addition, in order to prevent the protective layer 1011 from being corroded in a subsequent process (for example, in a process of forming an isolation portion described below in conjunction with FIGS. 6(a) and 6(b)) and thereby forming a gap between the support body 1013 and the stack, a plug 1015 may be formed above the support body 1013 in the opening. For a better size control, the plug 1015 may be formed by ALD followed by atomic layer etching (ALE). The plug 1015 may include a nitride.

The support body 1013 together with the protective layer 1011 (and optionally, the plug 1015) may be collectively referred to as the support portion.

For the purpose of electrical isolation, as shown in FIG. 6(a) and FIG. 6(b), an isolation portion 1017, such as a Shallow Trench Isolation (STI), may be formed on the substrate 1001. For example, the STI 1017 may be formed by depositing an oxide on the substrate, performing a planarization process such as Chemical Mechanical Polishing (CMP) on the deposited oxide, and etching back the planarized oxide by, for example, wet etching or vapor phase etching or dry etching. In addition, on a surface of the semiconductor layer patterned into the nanowire/nanosheet form on the substrate 1001, a thin etch stop layer 1017′ (e.g., with a thickness of about 1 nm to 5 nm) may be formed by, for example, deposition. Here, the etch stop layer 1017′ may also contain an oxide, and is thus shown as a thin layer integral with the STI 1017

In the embodiment, both the protective layer 1011 and the STI 1017 include an oxide. According to other embodiments of the present disclosure, in the case where the protective layer 1011 and the STI 1017 have etch selectivity between each other, a removal of the protective layer 1011 described above in conjunction with FIGS. 5(a) and 5 (b) may not be performed. Instead, the protective layer 1011 may be remained (and may be used as the etch stop layer 1017′, that is, without the process of separately forming the etch stop layer 1017′). In this case, the plug 1015 may not necessarily be formed.

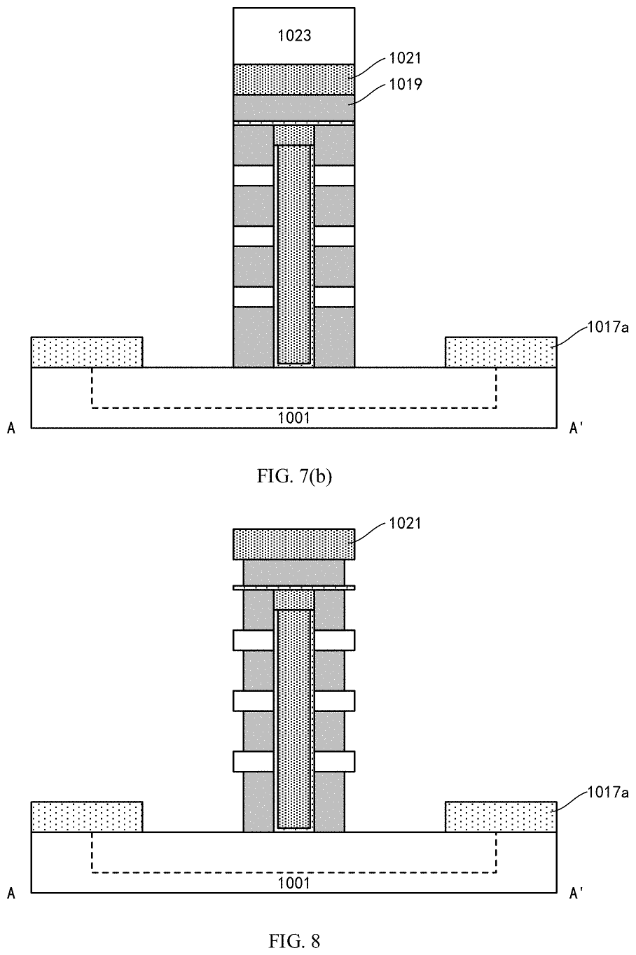

As described above, the gate defining layers 1007₁, 1007₂, 1007₃ are located on the upper and lower sides of the nanowire/nanosheet defining layers 1009₁, 1009₂. In order to form the gate-all-around, another gate defining layer may be formed on left and right sides in an orientation shown in FIG. 6(b). For example, as shown in FIG. 7(a) and FIG. 7(b), a gate defining layer 1019 may be formed on the STI 1017 and the etch stop layer 1017′. For example, the gate defining layer 1019 may be formed by depositing substantially the same or similar material as the gate defining layers 1007₁, 1007₂, 1007₃ (thereby having substantially the same or similar etching selectivity, so as to be processed together) and performing a planarization processing such as CMP on the deposited material. In the example, the gate defining layer 1019 may contain SiGe with an atomic percentage of Ge substantially the same as or similar to that of the gate defining layers 1007₁, 1007₂, 1007₃.

A hard mask layer 1021 may be formed on the gate defining layer 1019 by, for example, deposition, to facilitate patterning. For example, the hard mask layer 1021 may contain a nitride.

The gate defining layers 1007₁, 1007₂, 1007₃ and 1019 may be patterned into dummy gates extending in a direction (for example, the vertical direction on the paper surface in FIG. 7(a)) intersecting (for example, perpendicular to) the extension direction (for example, the horizontal direction on the paper surface in FIG. 7(a)) of the preliminary nanowire/nanosheet. For example, a photoresist 1023 may be formed on the hard mask layer 1021, and the photoresist 1023 may be patterned into a strip shape extending in the direction by photolithography. Then, the photoresist 1023 may be used as a mask, and each layer surrounded by the STI 1017 on the substrate 1001 may be selectively etched sequentially by, for example, RIE, and the etching may stop at the substrate 1001. As a result, the gate defining layers 1007₁, 1007₂, 1007₃ and 1019 are strip-shaped as a whole and may be collectively referred to as the “dummy gate”. In addition, the nanowire/nanosheet defining layers 1009₁ and 1009₂ may be formed as nanowires or nanosheets that may be used subsequently to provide channels (in the following, the nanowire/nanosheet defining layers 1009₁ and 1009₂ are referred to as nanowires/nanosheets 1009₁ and 1009₂), and are surrounded by the dummy gate, so that the Gate-All-Around structure may be formed later. The nanowires/nanosheets 1009₁ and 1009₂ may be self-aligned to the dummy gate. After that, the photoresist 1023 may be removed.

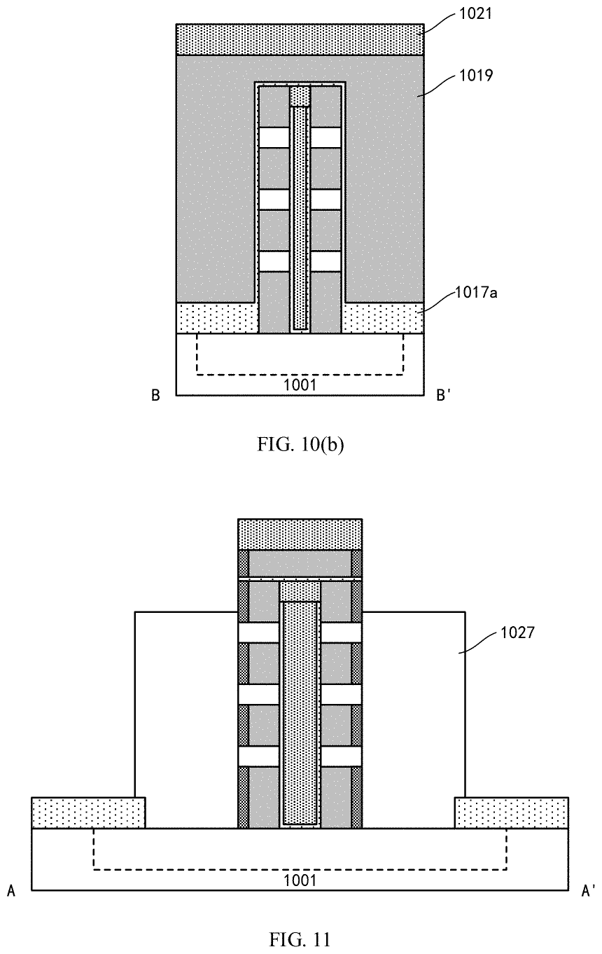

In addition, as shown in FIG. 7(b), on two sides of the dummy gate, the surface of the substrate 1001 is exposed by a remaining STI 1017a. The exposed surface may facilitate a subsequent growth of a source/drain layer. In addition, the STI 1017a may be connected to the isolation portion defining layer 1003 (see FIG. 10(b)) on two opposite sides of the extension direction of the dummy gate (the direction perpendicular to the paper surface in FIG. 7(b)).

In consideration of a limitation of a gate space and an isolation between the gate and the source/drain, a spacer may be formed on a sidewall of the dummy gate. In order to ensure identical gate lengths above and below each nanowire/nanosheet defining layer 1009₁, 1009₂, the spacer may be formed by using a self-alignment technology. For example, as shown in FIG. 8, the gate defining layers 1007₁, 1007₂, 1007₃, 1019 (SiGe in the example) may be selectively etched relative to the nanowires/nanosheets 1009₁, 1009₂ (Si in the example), so that sidewalls of the gate defining layers 1007₁, 1007₂, 1007₃, 1013 are recessed laterally by a depth of, for example, about 3 nm to 25 nm, with respect to a sidewall of the hard mask layer 1021 or sidewalls of the nanowires/nanosheets 1009₁, 1009₂. The recessed depths of the gate defining layers 1007₁, 1007₂, 1007₃, 1013 may be substantially the same, and the recessed depths at left and right sides may be substantially the same. For example, an Atomic Layer Etching (ALE) may be used to realize a good etch control. In the example, the isolation portion defining layer 1003 may also contain SiGe and therefore may also be recessed by substantially the same depth. Accordingly, the etched sidewalls of the gate defining layers 1007₁, 1007₂, 1007₃, 1019 (and the isolation portion defining layer 1003) may be substantially coplanar.

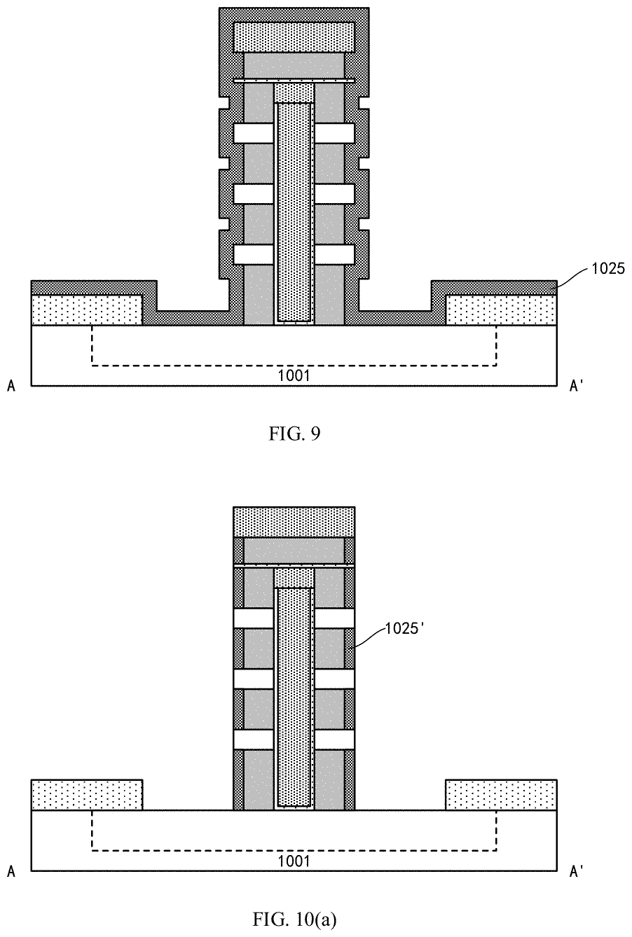

A spacer may be formed in the recess thus formed. As shown in FIG. 9, a dielectric material layer 1025 of a certain thickness may be formed on the substrate 1001 by, for example, deposition. A thickness of the deposited dielectric material layer 1025 may be, for example, about 3 nm to 15 nm, which is sufficient to fulfill the above-mentioned recess. For example, the dielectric material layer 1025 may contain SiC or the like.

After that, as shown in FIG. 10(a) and FIG. 10(b), the dielectric material layer 1025 may be selectively etched by, for example, RIE in the vertical direction, so that the dielectric material layer 1025 may be left in the above-mentioned recess to form a spacer 1025′. A sidewall of the spacer 1025′ may be substantially coplanar with the sidewall of the hard mask layer 1021 (and the sidewalls of the nanowires/nano sheets 1009₁, 1009₂).

As shown in FIG. 10(a) and FIG. 10(b), the sidewalls of each nanowire/nanosheet 1009₁, 1009₂ is exposed to an outside (and may be substantially coplanar with the sidewall of the hard mask layer) in a direction (e.g., the horizontal direction on the paper surface in FIG. 10(a)) intersecting (e.g., perpendicular to) the extension direction of the dummy gate (the direction perpendicular to the paper surface in FIG. 10(a)). As shown in FIG. 11, the exposed sidewalls of the nanowires/nanosheets 1009₁, 1009₂ (and the exposed surface of the substrate 1001) may be used as a seed to form a source/drain layer 1027 by, for example, selective epitaxial growth. The source/drain layer 1027 may be connected to the exposed sidewalls of all the nanowires/nanosheets 1009₁, 1009₂. The source/drain layer 1027 may contain various suitable semiconductor materials. In order to enhance a device performance, the source/drain layer 1027 may contain a semiconductor material having a lattice constant different from that of the nanowires/nanosheets 1009₁, 1009₂, so as to apply a stress to the nanowires/nanosheets 1009₁, 1009₂ in which a channel region is to be formed. For example, for an n-type device, the source/drain layer 1027 may contain Si:C (with an atomic percentage of C may be, for example, about 0.1% to 3%) to apply a tensile stress; for a p-type device, the source/drain layer 1027 may contain SiGe (with an atomic percentage of Ge may be, for example, about 20% to 80%) to apply a compressive stress. In addition, the source/drain layer 1027 may be doped to a desired conductivity type (n-type doping for the n-type device and p-type doping for the p-type device) by, for example, in-situ doping or ion implantation.

In the embodiment shown in FIG. 11, the source/drain layer grown from the sidewalls of the nanowires/nanosheets 1009₁, 1009₂ is connected to a source/drain layer grown from the surface of the substrate 1001, which may facilitate heat dissipation or enhancing a stress in the channel so as to improve the device performance. Alternatively, the source/drain layer grown from the sidewalls of the nanowires/nanosheets 1009₁, 1009₂ and the source/drain layer grown from the surface of the substrate 1001 may be spaced apart from each other.

Next, a replacement gate process may be performed.

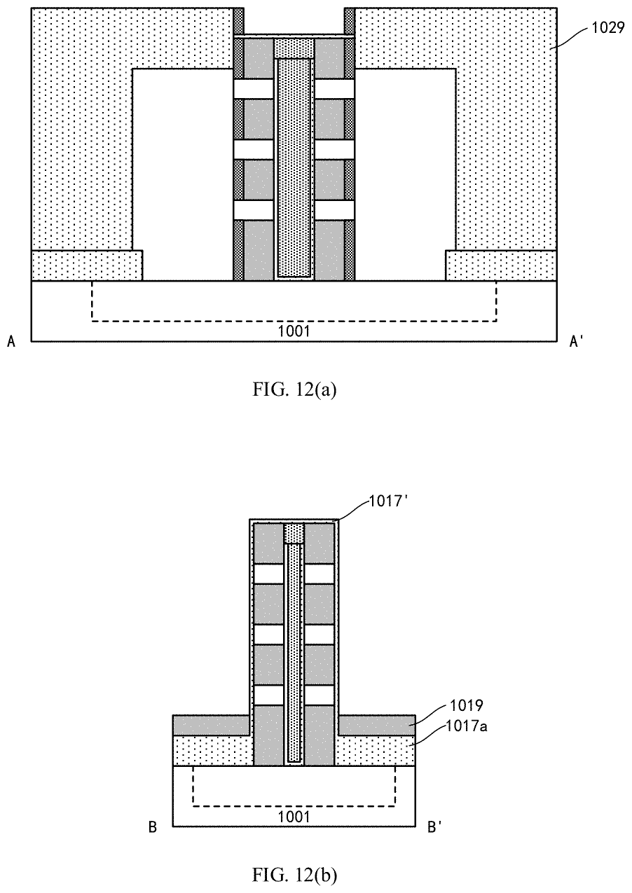

For example, as shown in FIG. 12(a) and FIG. 12(b), an interlayer dielectric layer 1029 may be formed on the substrate 1001. For example, the interlayer dielectric layer 1029 may be formed by depositing an oxide, performing a planarization process such as CMP on the deposited oxide, and etching back the planarized oxide. The interlayer dielectric layer 1029 may expose the hard mask layer 1021 while covering the source/drain layer 1027. After that, the hard mask layer 1021 may be removed by selective etching so as to expose the gate defining layer 1019.

In order to perform the replacement gate process, the dummy gate, i.e., all the gate defining layers 1007₁, 1007₂, 1007₃ and 1013 need to be removed and replaced with a gate stack. Here, in consideration of a formation of an isolation portion below the lowermost gate defining layer 1007₁, the isolation portion defining layer 1003 may be processed firstly. Specifically, the isolation portion defining layer 1003 is replaced with an isolation portion. To this end, a processing channel to the isolation portion defining layer 1003 may be formed.

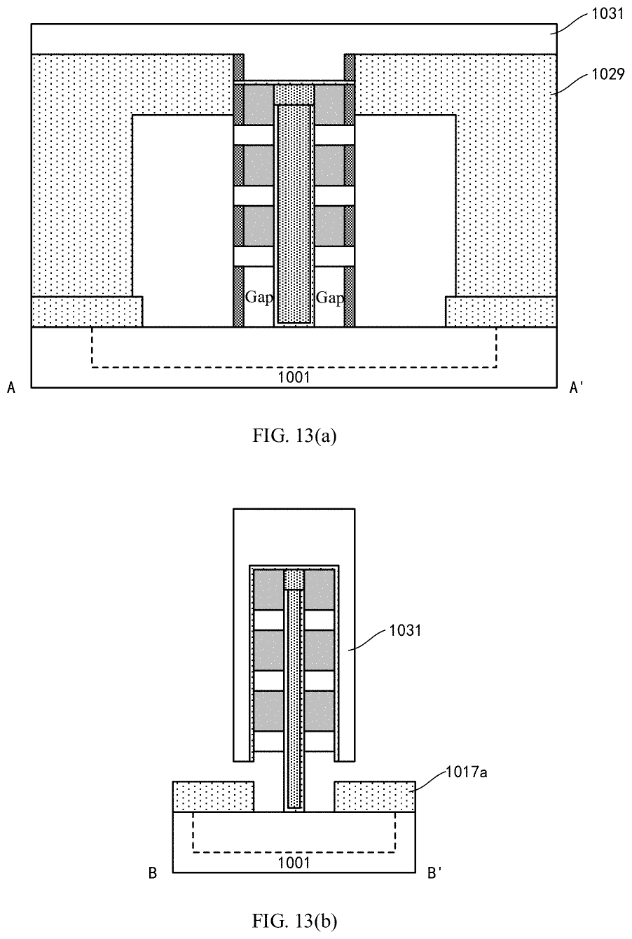

For example, a selective etching may be performed to reduce a height of a top surface of the gate defining layer 1019 to be lower than a top surface of the isolation portion defining layer 1003, but a certain thickness of the gate defining layer 1019 still remains so that a mask layer subsequently formed (1031 in FIG. 13(a) and FIG. 13(b)) may shield all the gate defining layers 1007₁, 1007₂, 1007₃ above the top surface of the isolation portion defining layer 1003 while exposing the isolation portion defining layer 1003. For example, ALE may be used to better control an etching depth. Here, other gate defining layers 1007₁, 1007₂, 1007₃ may not be affected due to an existence of the etch stop layer 1017′.

Then, as shown in FIG. 13(a) and FIG. 13(b), a mask layer such as a photoresist 1031 may be formed on the gate defining layer 1019. The photoresist 1031 may be patterned by photolithography into a strip shape extending in the extension direction of the nanowires/nanosheets 1009₁, 1009₂, the photoresist may shield outer surfaces of the nanowires/nanosheets 1009₁, 1009₂ and the gate defining layers 1007₁, 1007₂, 1007₃ (with the etch stop layer 1011′ interposed therebetween). Due to an existence of the gate defining layer 1019, a part of a surface of the isolation portion defining layer 1003 is not shielded by the photoresist 1031. After that, a selective etching may be performed to sequentially remove the gate defining layer 1019, a part of the etch stop layer 1017′ exposed by a removal of the gate defining layer 1019, and the isolation portion defining layer 1003 exposed by a removal of the portion of the etch stop layer 1017′. A gap is then formed below the etch stop layer 1005. Since the isolation portion defining layer 1003, the nanowire/nanosheet defining layers and the gate defining layer located above are defined by the same hard mask layer, the isolation portion defining layer 1003 may be aligned with the nanowire/nanosheet defining layers and the gate defining layer located above in the vertical direction. Accordingly, the gap formed by the removal of the isolation portion defining layer 1003 may be self-aligned with the nanowire/nanosheet defining layers and the gate defining layer located above. After that, the photoresist 1031 may be removed.

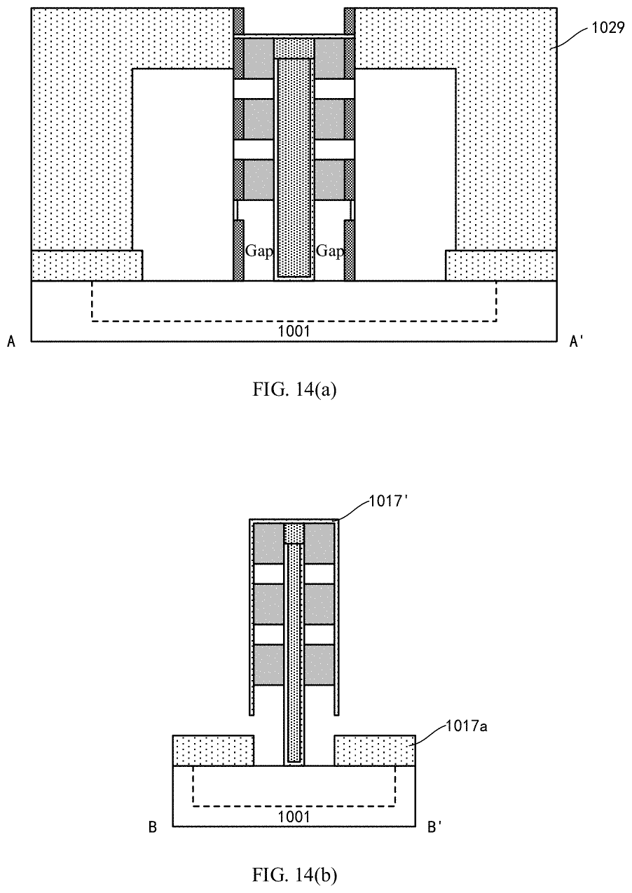

In the example, the etch stop layer 1005 may also contain a semiconductor material and is connected between opposite source/drain layers, which may result in a leakage path. To this end, as shown in FIG. 14(a) and FIG. 14(b), the etch stop layer 1005 may be cut off between the opposite source/drain layers by selective etching, for example, wet etching using a TMAH solution. Ends of the etch stop layer 1005 may be remained so as not to affect the source/drain layers on the two sides. On the other hand, the remained ends of the etch stop layer 1005 may not extend to an inner side of the spacer so as not to contact the gate defining layer (which is then replaced with the gate stack) on the inner side of the spacer. That is, an inner sidewall of the remained etch stop layer 1005 may be recessed with respect to an inner sidewall of the spacer. Since the etching is started from a middle, opposite ends of the remained etch stop layer 1005 may be substantially symmetrical. In addition, in the example, both the etch stop layer 1005 and the substrate 1001 contain silicon, thus a part of the substrate 1001 may also be etched (not shown). Therefore, the gap between the lowermost gate defining layer 10071 and the substrate 1001 may be enlarged, but may still be kept substantially aligned with the nanowire/nanosheet defining layers and the gate defining layer located above.

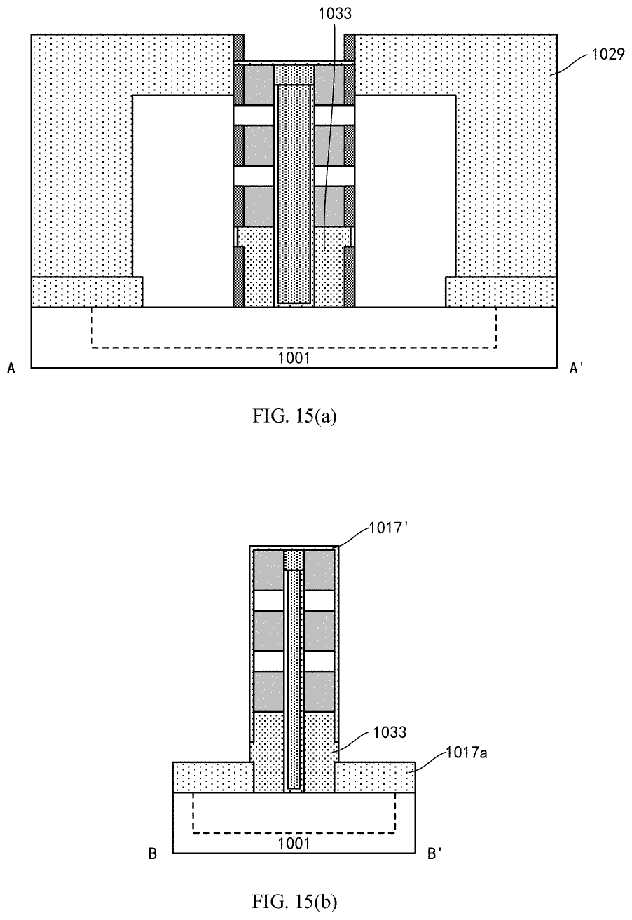

As shown in FIG. 15(a) and FIG. 15(b), the gap thus formed may be filled with a dielectric material, such as a low-k dielectric material, to form the isolation portion 1033. A material of the isolation portion 1033, for example, an oxynitride (e.g., silicon oxynitride), may have etching selectivity relative to the STI 1017a and the interlayer dielectric layer 1029. For example, the isolation portion 1033 may be formed by depositing sufficient oxynitride on the substrate 1001 and etching back the deposited oxynitride by, for example, RIE. The isolation portion 1033 thus formed may be self-aligned with the nanowire/nanosheet defining layers and the gate defining layer located above.

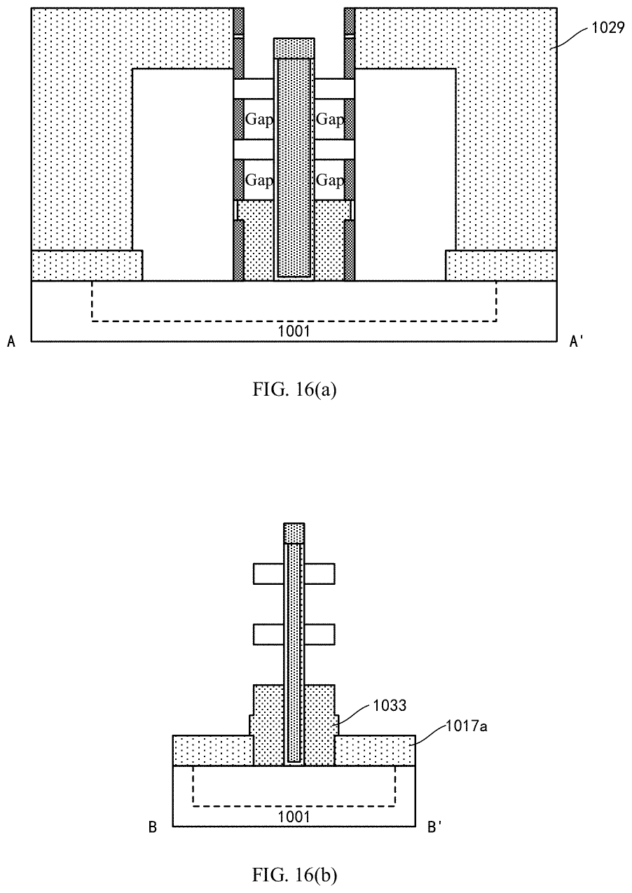

Next, as shown in FIGS. 16(a) and 16(b), the thin etch stop layer 1017′ may be removed by selective etching to expose the gate defining layers 1007₁, 1007₂ and 1007₃, and the gate defining layers 1007₁, 1007₂ and 1007₃ may be further removed by selective etching. Thus, a gate trench (corresponding to space originally occupied by each gate defining layer 1007₁, 1007₂, 1007₃ and 1019) may be formed above the STI 1017a and the isolation portion 1033 on the inner side of the spacer 1025′. The nanowires/nanosheets 1009₁ and 1009₂ are exposed in the gate trench. Due to an existence of the support portion, the nanowires/nanosheets 1009₁ and 1009₂ may be prevented from collapsing or adhering to each other during the manufacturing process.

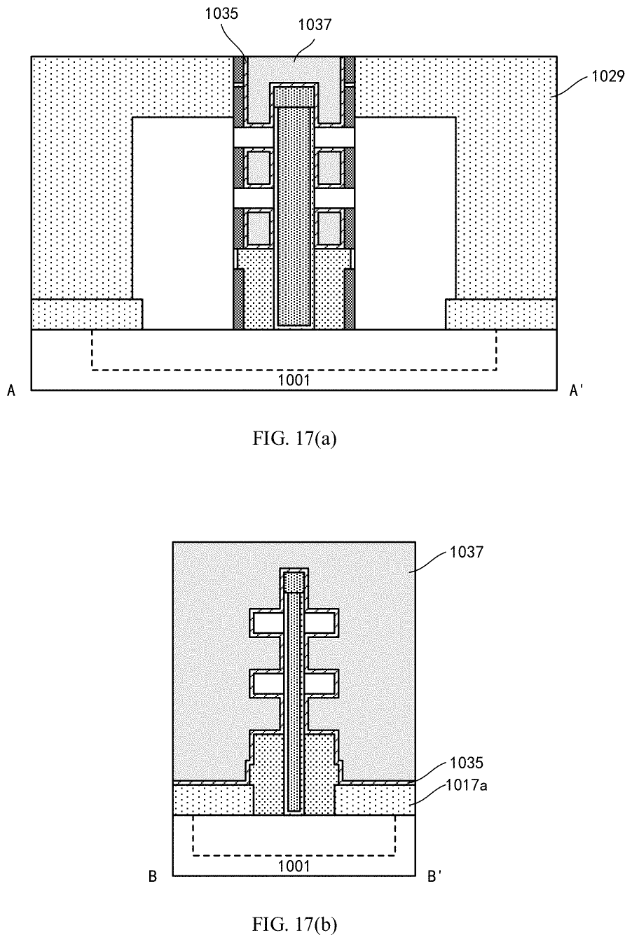

As shown in FIG. 17(a) and FIG. 17(b), a gate dielectric layer 1035 and a gate electrode 1037 may be sequentially formed in the gate trench so as to obtain a final gate stack. For example, the gate dielectric layer 1035 may contain a high-k gate dielectric such as HfO₂ with a thickness of about 2 nm to 10 nm; the gate electrode 1035 may include a work function adjustment layer such as TiN, TiAlN, TaN, etc., and a gate conductor layer such as W, Co, Ru, etc. An interface layer of, for example, an oxide formed by an oxidation process or deposition such as Atomic Layer Deposition (ALD) with a thickness of about 0.3 nm to 2 nm, may be further formed before the high-k gate dielectric is formed.

As shown in FIG. 17(a) and FIG. 17(b), the nanowire/nanosheet device according to the embodiment may include (fewer or more) nanowires/nanosheets 1009₁, 1009₂ spaced apart from the substrate 1001 and the gate stack surrounding the nanowires/nanosheets 1009₁, 1009₂. The gate stack includes the gate dielectric layer 1035 and the gate electrode 1037. The support portion (including the support body 1013, the protective layer 1011 and optionally the plug 1015) penetrates each of the nanowires/nanosheets 1009₁, 1009₂ to support the nanowires/nanosheets 1009₁, 1009₂.

The spacers 1025′ may be formed on a sidewall of the gate stack. The inner sidewalls of the spacers 1025′ may be substantially coplanar in the vertical direction so as to provide substantially the same gate length. In addition, Outer sidewalls of the spacer 1025′ may also be coplanar in the vertical direction, and may be coplanar with corresponding sidewalls of the nanowires/nanosheets 1009₁, 1009₂.

The nanowire/nanosheet device may further include the isolation portion 1033. As described above, the isolation portion 1033 may be self-aligned with the gate stack or the nanowires/nanosheets 1009₁, 1009₂, and then at least a part of the sidewall of the isolation portion 1033 may be aligned with the corresponding sidewall of the gate stack located above in the vertical direction. For example, as shown in FIG. 17(a), at least a part of each of the opposite sidewalls of the isolation portion 1033 in the extension direction (the horizontal direction on the paper surface in the drawing) of the nanowire/nanosheet may be aligned with the sidewall of the corresponding gate stack in the vertical direction. In addition, as shown in FIG. 17(b), at least a part of each of the opposite sidewalls of the isolation portion 1033 in the extension direction (the horizontal direction on the paper surface in the drawing) of the gate may be aligned with the sidewall of the corresponding gate stack in the vertical direction. A part of each of the sidewall of the isolation portion 1033 not coplanar with the corresponding sidewall of the gate stack (if existing; the portions are formed by the process and may not exist depending on the process) may extend substantially conformally with the corresponding sidewall of the gate stack.

The spacer 1025′ may be further formed on the sidewall of the isolation portion 1033. An upper portion of the isolation portion 1033 may be interposed between upper and lower portions of the spacer 1025′, but does not extend beyond the outer sidewall of the spacer 1025′.

As described above, the isolation portion 1033 is aligned with the nanowires/nanosheets 1009₁ and 1009₂ in the vertical direction. In addition, as shown in FIG. 17(b), the isolation portion 1033 is in contact with the STI 1017a on the two opposite sides of the extension direction (the horizontal direction on the paper in the drawing) of the gate, so that the gate stack is isolated from the substrate by both the isolation portion 1033 and the STI 1017a.

In the above embodiments, the support portion is formed of the dielectric material to support the nanowire/nanosheet. However, the present disclosure is not limited to this.

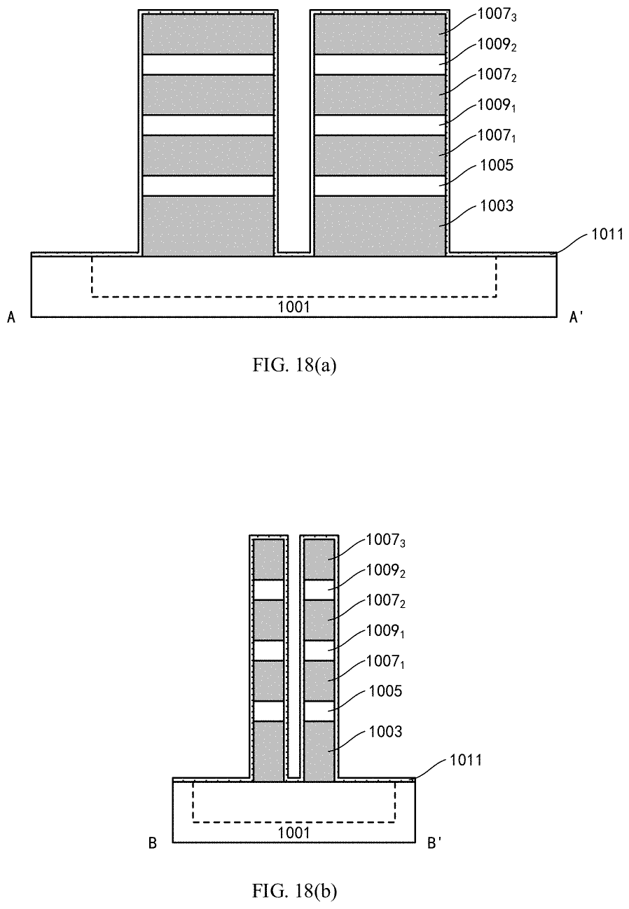

As shown in FIGS. 18(a) and 18(b), as described above in conjunction with FIGS. 2(a) to 2(c) and FIG. 3, an opening is defined in nanowire/nanosheet defining layers 1009₁ and 1009₂. A protective layer 1011 may be formed as described above in connection with FIGS. 4(a) and 4(b). In the opening, a conductive material may be filled instead of filling the dielectric material as described above. The conductive material may not only support the nanowires/nanosheets as described above, but may also be used as the inner gate.

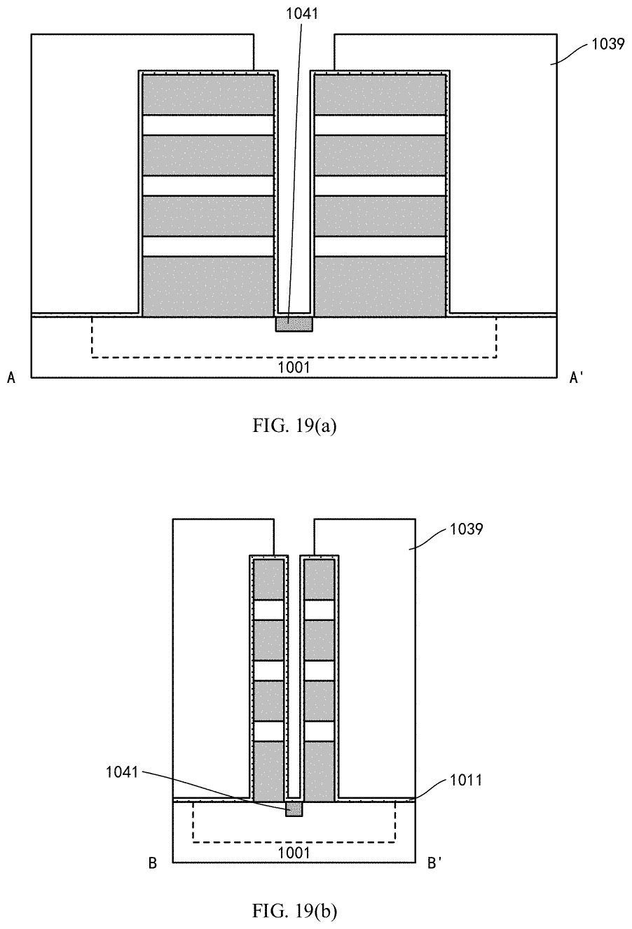

In order to better apply a signal to the conductive material, as shown in FIGS. 19(a) and 19(b), a contact region 1041 may be formed at a bottom of the opening. For example, a photoresist 1039 may be formed and patterned to expose the opening. Then, a highly doped region may be formed in the substrate 1001 through the opening by, for example, ion implantation to form thee contact region 1041. After that, the photoresist 1039 may be removed.

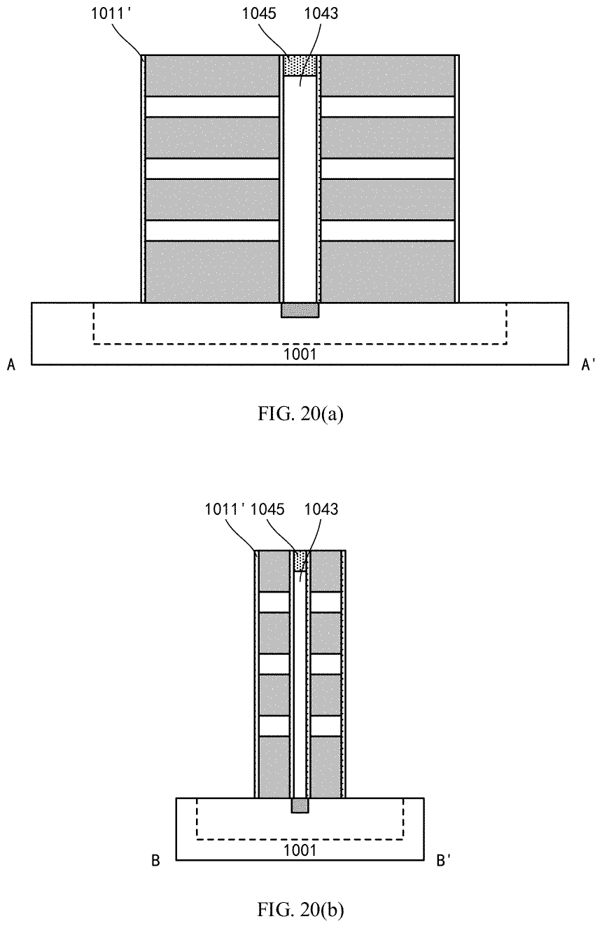

As shown in FIGS. 20(a) and 20(b), the protective layer 1011 at the bottom of the opening may be removed by, for example, RIE in the vertical direction, so that the conductive material subsequently filled in the opening may directly contact the contact region 1041 and thus form an electrical connection. When the protective layer 1011 at the bottom of the opening is removed, other laterally extended parts of the protective layer 1011 may also be removed, thereby leaving vertically extending parts 1011′ of the protective layer. After that, a conductive material 1043 such as (doped) polysilicon may be filled into the opening, and a plug 1045 may be formed. The filling of the conductive material 1043 and a formation of the plug 1045 may be substantially the same as the formation of the support body 1013 and the plug 1015 described above. The conductive material 1043 (also referred to as the support body) and the protective layer 1011′ (and optionally, the plug 1045) may be collectively referred to as the support portion. The (oxide) protective layer 1011′ and the (polysilicon) conductive material 1043 may form the inner gate.

According to another embodiment, the protective layer 1011 (1011′) may include a high-k dielectric, and the conductive material 1043 may include a metal, so that the protective layer 1011′ and the conductive material 1043 may form a high-k metal gate stack for use as the inner gate.

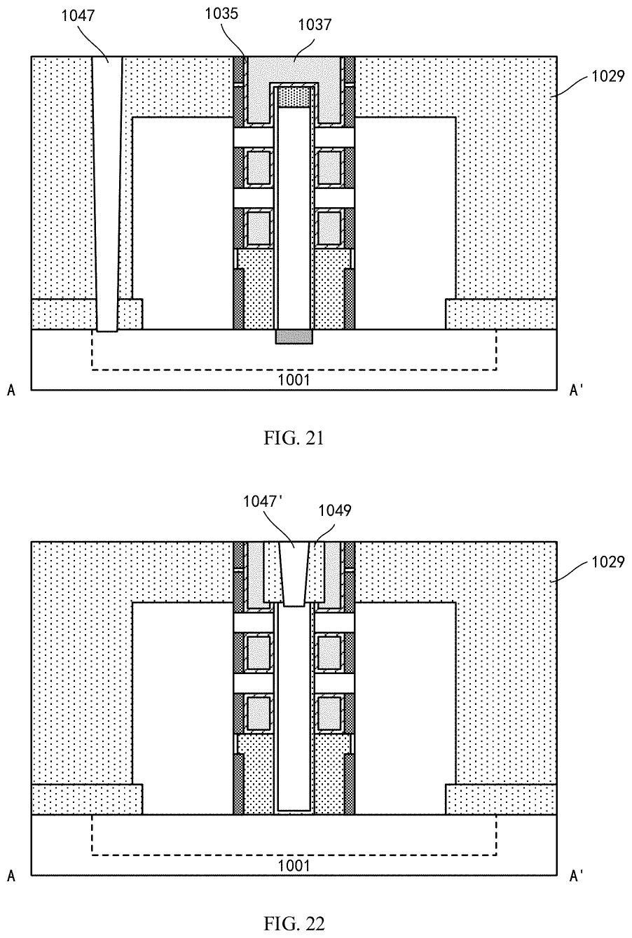

The following process may be performed as described in the above-mentioned embodiments, and a device shown in FIG. 21 may be obtained. The device shown in FIG. 21 is substantially the same as the device described above in conjunction with FIGS. 17(a) and 17(b), except that the support body 1013 is replaced with the conductive material. As shown in FIG. 21, an electrical signal may be applied to the inner gate via a contact plug 1047 through the well region and the contact region 1041. Thus, a current between the source/drain layers may be controlled or a threshold voltage of the device may be dynamically adjusted.

Alternatively, as shown in FIG. 22, instead of applying the electrical signal to the inner gate from the lower side as described above, a contact plug 1047′ that directly reaches the inner gate (specifically, the conductive material 1043) is formed above the inner gate. In this case, the contact region 1041 may not necessarily be formed. In addition, an isolation material 1049 such as an oxide may be provided between the contact plug 1047′ and the gate electrode 1037 above the inner gate, so as to electrically isolate the contact plug 1047′ from the gate electrode 1037.

The nanowire/nanosheet device according to the embodiments of the present disclosure may be applied to various electronic apparatuses. For example, an Integrated Circuit (IC) may be formed based on the nanowire/nanosheet device, and thus an electronic apparatus may be constructed. Accordingly, the present disclosure further provides an electronic apparatus including the nanowire/nanosheet device described above. The electronic apparatus may further include a display screen cooperating with the integrated circuit, a wireless transceiver cooperating with the integrated circuit, and other components. The electronic apparatus may include, for example, a smart phone, a Personal Computer (PC), a tablet computer, an artificial intelligence apparatus, a wearable apparatus or a portable power supply, etc.

According to the embodiments of the present disclosure, there is further provided a method of manufacturing a System on Chip (SoC). The method may include the method described above. In particular, various devices may be integrated on a chip, at least some of which are manufactured according to the method of the present disclosure.

In the above descriptions, technical details such as patterning and etching of each layer have not been described in detail. However, those skilled in the art should understand that various technical means may be used to form layers, regions, etc. of desired shapes. In addition, in order to form the same structure, those skilled in the art may further design a method that is not completely the same as the method described above. In addition, although the embodiments are described above separately, this does not mean that the measures in the embodiments may not be advantageously used in combination.

The embodiments of the present disclosure have been described above. However, these embodiments are for illustrative purposes only, and are not used to limit the scope of the present disclosure. The scope of the present disclosure is defined by the appended claims and their equivalents. Without departing from the scope of the present disclosure, those skilled in the art may make various substitutions and modifications, and these substitutions and modifications should all fall within the scope of the present disclosure.

What is claimed is:

1. A nanowire/nanosheet device, comprising:
a substrate;
a first source/drain layer and a second source/drain layer opposite to each other in a first direction on the substrate;
a first nanowire/nanosheet spaced apart from a surface of the substrate and extending from the first source/drain layer to the second source/drain layer;
one or more support portions penetrating the first nanowire/nanosheet in a direction perpendicular to the surface of the substrate; and
a gate stack extending in a second direction to surround the first nanowire/nanosheet, wherein the second direction intersects the first direction.

2. The nanowire/nanosheet device according to claim 1, further comprising:
a second nanowire/nanosheet spaced apart from the surface of the substrate and extending from the first source/drain layer to the second source/drain layer, wherein the first nanowire/nanosheet and the second nanowire/nanosheet are at different heights relative to the substrate,
wherein the support portion further penetrates the second nanowire/nanosheet in the vertical direction, and is physically connected to the first nanowire/nanosheet and the second nanowire/nanosheet, and
wherein the gate stack surrounds the second nanowire/nanosheet.

3. The nanowire/nanosheet device according to claim 2, wherein the first nanowire/nanosheet and the second nanowire/nanosheet are substantially aligned in the vertical direction.

4. The nanowire/nanosheet device according to claim 1, wherein a minimum dimension of the support portion is 5 nm to 30 nm.

5. The nanowire/nanosheet device according to claim 1, wherein a spacing between the plurality of support portions is 5 nm to 20 nm.

6. The nanowire/nanosheet device according to claim 1, wherein the support portion comprises a dielectric material.

7. The nanowire/nanosheet device according to claim 1, wherein the support portion comprises a laminate of a dielectric material and a conductive material.

8. The nanowire/nanosheet device according to claim 7, further comprising:
a contact plug configured to apply an electrical signal to the conductive material.

9. The nanowire/nanosheet device according to claim 7, wherein the support portion is configured to control a current between the first source/drain layer and the second source/drain layer or adjust a threshold voltage of the nanowire/nanosheet device.

10. A method of manufacturing a nanowire/nanosheet device, comprising:
forming a stack of one or more gate defining layers and one or more nanowire/nanosheet defining layers alternately arranged on a substrate;
patterning the stack into a linear shape or a sheet shape extending in a first direction, with one or more openings penetrating the stack in a direction perpendicular to a surface of the substrate;
forming a support portion in the one or more openings;
forming another gate defining layer on the substrate to cover the stack;
patterning the another gate defining layer into a strip shape extending in a second direction intersecting the first direction;
patterning the stack by using the strip-shaped another gate defining layer as a mask, wherein the patterned nanowire/nanosheet defining layer forms a nanowire/nanosheet, and the patterned gate defining layer and the another gate defining layer form a dummy gate; and
replacing the dummy gate with a gate stack.

11. The method according to claim 10, further comprising:
forming a spacer on a sidewall of the dummy gate,
wherein the replacing the dummy gate with a gate stack comprises: removing the dummy gate, and forming the gate stack in a space left inside the spacer due to a removal of the dummy gate.

12. The method according to claim 10, further comprising:
forming an isolation portion defining layer on the substrate, wherein the stack is formed on the isolation portion defining layer, and
wherein the removing the dummy gate comprises:
removing the another gate defining layer;
removing the isolation portion defining layer through the space left inside the spacer due to the removal of the another gate defining layer, and forming an isolation portion in a space left under the stack due to the removal of the isolation portion defining layer; and
removing the gate defining layer.

13. The method according to claim 10, wherein a minimum dimension of the opening is 5 nm to 30 nm.

14. The method according to claim 10, wherein an spacing between the plurality of openings is 5 nm to 20 nm.

15. The method according to claim 10, wherein the support portion comprises a dielectric material.

16. The method according to claim 10, wherein the support portion comprises a laminate of a dielectric material and a conductive material.

17. An electronic apparatus comprising the nanowire/nanosheet device according to claim 1.

18. The electronic apparatus according to claim 17, wherein the electronic apparatus comprises a smart phone, a personal computer, a tablet computer, an artificial intelligence device, a wearable device or a power supply.
